(19) United States
(12) Patent Application Publication
(10) Pub. No.: US 2026/0059641 A1
(43) Pub. Date: Feb. 26, 2026

(54) EUV LIGHT GENERATION APPARATUS AND ELECTRONIC DEVICE MANUFACTURING METHOD

(71) Applicant: Gigaphoton Inc., Tochigi (JP)

(72) Inventors: Takayuki SUZUKI, Oyama-shi (JP); Hirokazu HOSODA, Oyama-shi (JP)

(73) Assignee: Gigaphoton Inc., Tochigi (JP)

(21) Appl. No.: 19/257,405

(22) Filed: Jul. 1, 2025

(30) Foreign Application Priority Data
Aug. 26, 2024 (JP) 2024-144076

(51) Int. Cl. H05G 2/00; G03F 7/00

(52) U.S. Cl. CPC H05G 2/0086; G03F 7/70033; H05G 2/0027

(57) ABSTRACT

An EUV light generation apparatus includes a chamber; a target supply device configured to supply a target into the chamber; a first pulse laser device configured to irradiate the target with first pulse laser light in a plasma generation region in the chamber; an EUV light concentrating mirror arranged in the chamber and configured to reflect EUV light, radiated from the plasma generation region, toward an external apparatus; and a second pulse laser device configured to irradiate a diffusion matter, diffused by the irradiation with the first pulse laser light, with second pulse laser light having an irradiation spot diameter larger than an irradiation spot diameter of the first pulse laser light. An intensity of the EUV light generated by the irradiation with the second pulse laser light is smaller than an intensity of the EUV light generated by the irradiation with the first pulse laser light.

### CROSS-REFERENCE TO RELATED APPLICATIONS

The present application claims the benefit of Japanese Patent Application No. 2024-144076, filed on Aug. 26, 2024, the entire contents of which are hereby incorporated by reference.

### BACKGROUND

### 1. Technical Field

The present disclosure relates to an EUV light generation apparatus and an electronic device manufacturing method.

### 2. Related Art

Recently, miniaturization of a transfer pattern in optical lithography of a semiconductor process has been rapidly proceeding along with miniaturization of the semiconductor process. In the next generation, microfabrication at 10 nm or less will be required. Therefore, it is expected to develop a semiconductor exposure apparatus that combines an apparatus for generating extreme ultraviolet (EUV) light having a wavelength of about 13 nm with a reduced projection reflection optical system.

As the EUV light generation apparatus, a laser produced plasma (LPP) type apparatus using plasma generated by irradiating a target with laser light has been developed.

### LIST OF DOCUMENTS

### Patent Documents

Patent Document 1: Japanese Patent Application Publication No. 2010-186995
Patent Document 2: Japanese Patent No. 6799645

### SUMMARY

An EUV light generation apparatus according to an aspect of the present disclosure includes a chamber; a target supply device configured to supply a target into the chamber; a first pulse laser device configured to irradiate the target with first pulse laser light in a plasma generation region in the chamber; an EUV light concentrating mirror arranged in the chamber and configured to reflect EUV light, radiated from the plasma generation region, toward an external apparatus; and a second pulse laser device configured to irradiate a diffusion matter, diffused by the irradiation with the first pulse laser light, with second pulse laser light having an irradiation spot diameter larger than an irradiation spot diameter of the first pulse laser light. Here, an intensity of the EUV light generated by the irradiation with the second pulse laser light is smaller than an intensity of the EUV light generated by the irradiation with the first pulse laser light.

An electronic device manufacturing method according to an aspect of the present disclosure includes outputting EUV light generated by an EUV light generation apparatus to an exposure apparatus, and exposing a photosensitive substrate to the EUV light in the exposure apparatus to manufacture an electronic device. Here, the EUV light generation apparatus includes a chamber; a target supply device configured to supply a target into the chamber; a first pulse laser device configured to irradiate the target with first pulse laser light in a plasma generation region in the chamber; an EUV light concentrating mirror arranged in the chamber and configured to reflect the EUV light, radiated from the plasma generation region, toward an external apparatus; and a second pulse laser device configured to irradiate a diffusion matter, diffused by the irradiation with the first pulse laser light, with second pulse laser light having an irradiation spot diameter larger than an irradiation spot diameter of the first pulse laser light. An intensity of the EUV light generated by the irradiation with the second pulse laser light is smaller than an intensity of the EUV light generated by the irradiation with the first pulse laser light.

An electronic device manufacturing method according to an aspect of the present disclosure includes inspecting a defect of a mask by irradiating the mask with EUV light generated by an EUV light generation apparatus, selecting a mask using a result of the inspection, and exposing and transferring a pattern formed on the selected mask onto a photosensitive substrate. Here, the EUV light generation apparatus includes a chamber; a target supply device configured to supply a target into the chamber; a first pulse laser device configured to irradiate the target with first pulse laser light in a plasma generation region in the chamber; an EUV light concentrating mirror arranged in the chamber and configured to reflect the EUV light, radiated from the plasma generation region, toward an external apparatus; and a second pulse laser device configured to irradiate a diffusion matter, diffused by the irradiation with the first pulse laser light, with second pulse laser light having an irradiation spot diameter larger than an irradiation spot diameter of the first pulse laser light. An intensity of the EUV light generated by the irradiation with the second pulse laser light is smaller than an intensity of the EUV light generated by the irradiation with the first pulse laser light.

### BRIEF DESCRIPTION OF THE DRAWINGS

An embodiment of the present disclosure will be described below merely as examples with reference to the accompanying drawings.

FIG. 1 is a schematic view of an EUV light generation apparatus according to a comparative example as viewed in the horizontal direction.

FIG. 2 is a schematic view of the EUV light generation apparatus according to the comparative example as viewed in the vertical direction.

FIG. 3 is a schematic view of the EUV light generation apparatus according to the comparative example showing a state after being operated for a certain period of time.

FIG. 4 is an enlarged view showing a state of the vicinity of a plasma generation region in FIG. 3.

FIG. 5 is a schematic view of the EUV light generation apparatus according to an embodiment as viewed in the vertical direction.

FIG. 6 is a diagram schematically showing PPL light, MPL light, and CUL light radiated to one target.

FIG. 7 is a diagram showing the relationship between a pulse width of the MPL light and a pulse width of the CUL light.

FIG. 8 is a diagram showing a modification of a laser device.

FIG. 9 is a diagram showing another modification of the laser device.

FIG. 10 is a diagram schematically showing the configuration of an exposure apparatus.

FIG. 11 is a diagram schematically showing the configuration of an inspection apparatus.

### DESCRIPTION OF EMBODIMENTS

### <Contents>

1. Comparative example
   1.1 Configuration
   1.2 Operation
   1.3 Problem
2. Embodiment
   2.1 Configuration
   2.2 Operation
   2.3 Irradiation conditions of CUL light
      2.3.1 Irradiation spot diameter
      2.3.2 Irradiation timing
      2.3.3 Irradiation intensity
      2.3.4 Pulse width
   2.4 Effect
3. Modification
4. Electronic device manufacturing method

Hereinafter, an embodiment of the present disclosure will be described in detail with reference to the drawings. The embodiment described below shows some examples of the present disclosure and do not limit the contents of the present disclosure. Also, all configurations and operation described in the embodiment are not necessarily essential as configurations and operation of the present disclosure. Here, the same components are denoted by the same reference numeral, and duplicate description thereof is omitted.

### 1. Comparative Example

### 1.1 Configuration

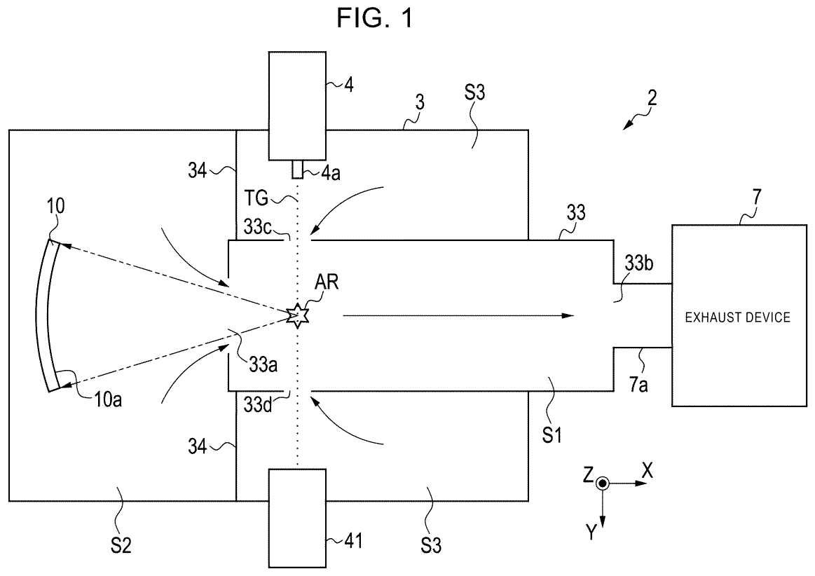

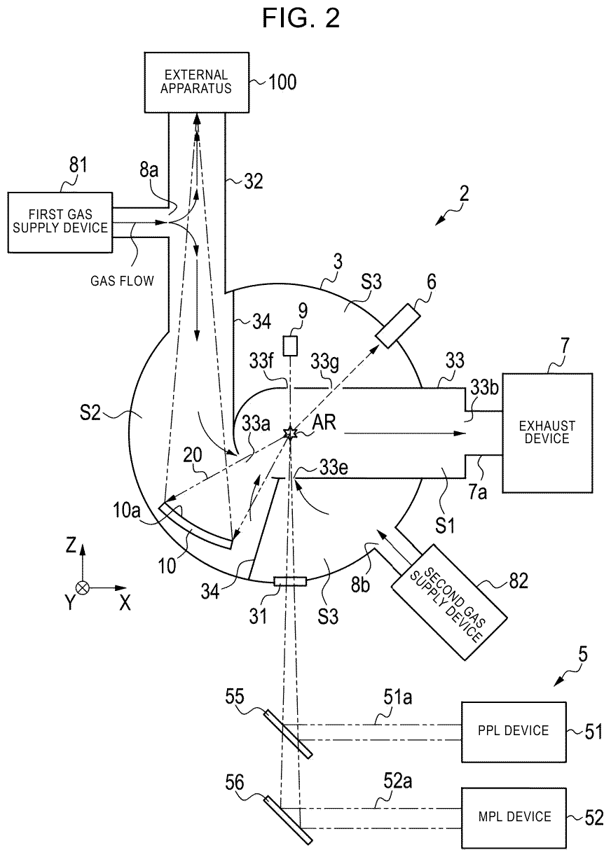

FIGS. 1 and 2 schematically show the configuration of an EUV light generation apparatus 2 according to a comparative example. FIG. 1 is a schematic view of the EUV light generation apparatus 2 as viewed in the horizontal direction. FIG. 2 is a schematic view of the EUV light generation apparatus 2 as viewed in the vertical direction.

The EUV light generation apparatus 2 includes a chamber 3, a target supply device 4, and a laser device 5. The chamber 3 is a sealable container. The target supply device 4 supplies a droplet-shaped target TG into the chamber 3. The target TG is liquid tin. The target supply device 4 outputs the target TG from a nozzle 4a at a constant cycle toward a plasma generation region AR located vertically below the nozzle 4a. The diameter of the target TG is 10 μm to 30 μm.

A window 31 for causing pulse laser light output from the laser device 5 arranged outside the chamber 3 to enter the inside thereof is formed at the chamber 3. The pulse laser light transmitted through the window 31 is radiated to the target TG in the plasma generation region AR.

The chamber 3 is connected with a connection pipe 32 for providing communication between the inside of the chamber 3 and the inside of an external apparatus 100. The external apparatus 100 is an exposure apparatus 100a or an inspection apparatus 100b.

A first gas supply port 8a is formed at the connection pipe 32. A first gas supply device 81 is connected to the first gas supply port 8a. The first gas supply device 81 includes a gas tank and supplies a gas into the chamber 3 through the connection pipe 32. Further, a second gas supply port 8b is formed at the chamber 3. A second gas supply device 82 is connected to the second gas supply port 8b. The second gas supply device 82 includes a gas tank and supplies the gas into the chamber 3. The first gas supply device 81 may be directly connected to the chamber 3.

The gas supplied by the first gas supply device 81 and the second gas supply device 82 includes, for example, a hydrogen gas. The gas may be a hydrogen gas having a hydrogen concentration of 100%. The gas may be a balance gas having a hydrogen gas concentration of about 3%. In this case, the balance gas includes, for example, a nitrogen (N₂) gas or an argon (Ar) gas. Each of the first gas supply device 81 and the second gas supply device 82 may be provided with a flow rate adjustment valve capable of adjusting the flow rate of the gas.

A sensor 6 for measuring the intensity of EUV light 20 generated in the plasma generation region AR is attached to the chamber 3.

A target collection device 41 is provided in the chamber 3 at a position facing the target supply device 4. The target collection device 41 is a drain tank that collects unnecessary target TG not having contributed to the generation of the EUV light 20 in the plasma generation region AR.

A cylindrical partition wall 33 extending from an internal space of the chamber 3 to an external space thereof is provided at the chamber. The partition wall 33 surrounds the plasma generation region AR. The partition wall 33 is formed of stainless steel, metal molybdenum, or the like. Among two opposite end portions of the partition wall 33, a gas inlet port 33a is formed at an end portion located in the internal space, and a gas outlet port 33b is formed at an end portion located in the external space. The gas outlet port 33b is connected via a pipe 7a to an exhaust device 7 including an exhaust pump. The exhaust device 7 exhausts the gas supplied from the first gas supply device 81 and the second gas supply device 82 into the chamber 3. A target introduction port 33c and a target discharge port 33d are formed at the partition wall 33. The target introduction port 33c and the target discharge port 33d are arranged so as to face each other on the trajectory of the target TG.

A laser entrance port 33e and a laser exit port 33f are formed at the partition wall 33. The laser entrance port 33e and the laser exit port 33f are arranged so as to face each other on the optical path of the pulse laser light that is transmitted through the window 31 and enters the chamber 3.

A monitor opening 33g is formed at the partition wall 33. The monitor opening 33g is arranged between the plasma generation region AR and the sensor 6. Observation light generated at or near the plasma generation region AR passes through the monitor opening 33g and enters the sensor 6.

A partition wall 34 for dividing an external space of the partition wall 33 into two spaces is provided in the chamber 3. The partition wall 34 is connected between an inner wall of the chamber 3 and the partition wall 33. The partition wall 34 is formed of stainless steel, metal molybdenum, or the like.

Hereinafter, the internal space of the partition wall 33 is referred to as a first space S1. Further, of the two spaces outside the partition wall 33 divided by the partition wall 34, the space communicating with the connection pipe 32 is referred to as a second space S2 and the space not communicating with the connection pipe 32 is referred to as a third space S3. The plasma generation region AR is located in the first space S1. The gas inlet port 33a is formed between the first space S1 and the second space S2. The target introduction port 33c, the target discharge port 33d, the laser entrance port 33e, and the laser exit port 33f are formed between the first space S1 and the third space S3.

An EUV light concentrating mirror 10 having a part of a spheroidal surface as a reflection surface 10a is arranged in the second space S2. A multilayer reflective film in which molybdenum and silicon are alternately laminated is formed on the reflection surface 10a. The EUV light concentrating mirror 10 is arranged such that one focal point of the spheroidal surface is located in the plasma generation region AR.

The EUV light 20 radiated from the plasma in the plasma generation region AR is incident on the EUV light concentrating mirror 10 arranged in the second space S2 from the first space S1 through the gas inlet port 33a. The EUV light concentrating mirror 10 reflects the EUV light 20 toward the external apparatus 100 located in a direction different from the incident direction.

The second gas supply port 8b is formed at a position communicating with the third space S3. The sensor 6 is arranged in the third space S3. A damper 9 for absorbing the pulse laser light entering the third space S3 from the plasma generation region AR through the laser exit port 33f is arranged in the third space S3.

The laser device 5 is arranged such that the output pulse laser light enters the third space S3 in the chamber 3 through the window 31 and enters the plasma generation region AR through the laser entrance port 33e.

The laser device 5 outputs prepulse laser (PPL) light 51a and main pulse laser (MPL) light 52a as pulse laser light. Specifically, the laser device 5 includes a PPL device 51 that outputs the PPL light 51a, and a MPL device 52 that outputs the MPL light 52a. For example, the PPL device 51 is an Nd: YAG laser device, and the MPL device 52 is an Nd: YAG laser device or a CO₂ laser device. For example, a wavelength λ1 of the PPL light 51a is equal to a wavelength λ2 of the MPL light 52a, and is 1.06 μm. The PPL light 51a and the MPL light 52a are linearly polarized.

A beam combiner 55 is provided to cause the PPL light 51a and the MPL light 52a to enter the chamber 3 through the window 31 with optical paths thereof integrated. The beam combiner 55 is, for example, a polarization beam splitter that reflects s-polarized light and transmits p-polarized light. The beam combiner 55 is arranged such that the PPL light 51a output from the PPL device 51 is incident on one surface thereof as s-polarized light, and the MPL light 52a output from the MPL device 52 and reflected by the reflection mirror 56 is incident on the other surface thereof as p-polarized light. The PPL light 51a is reflected by the beam combiner 55 and the MPL light 52a is transmitted through the beam combiner 55, so that the optical paths of the PPL light 51a and the MPL light 52a are integrated.

Here, the reflection mirror 56 is not necessarily required, and the MPL light 52a output from the MPL device 52 may be directly incident on the beam combiner 55. When the wavelength λ1 of the PPL light 51a differs from the wavelength λ2 of the MPL light 52a, the beam combiner 55 may be a dichroic mirror.

The pulse energy of the PPL light 51a is smaller than the pulse energy of the MPL light 52a. The laser device 5 outputs the PPL light 51a and the MPL light 52a in this order.

Here, an X direction shown in FIGS. 1 and 2 is a direction from the plasma generation region AR toward the exhaust device 7, a Y direction is the vertical direction, and a Z direction is a direction along the optical path of the pulse laser light. In the comparative example, the X direction, the Y direction, and the Z direction are orthogonal to each other, but are not necessarily orthogonal to each other.

### 1.2 Operation

The operation of the EUV light generation apparatus 2 according to the comparative example will be described. First, the pressure in the chamber 3 is set to a predetermined pressure or less. Thereafter, the supply of the gas from the first gas supply device 81 and the second gas supply device 82 into the chamber 3 is started. The gas supplied from the first gas supply device 81 flows from the second space S2 into the first space S1 through the gas inlet port 33a. The gas supplied from the second gas supply device 82 flows from the third space S3 into the first space S1 via the target introduction port 33c, the target discharge port 33d, the laser entrance port 33e, the laser exit port 33f, and the monitor opening 33g. The gas having flowed into the first space S1 flows out from the gas outlet port 33b and is discharged to the outside of the chamber 3 by the exhaust device 7.

Next, the target supply device 4 outputs the target TG from the nozzle 4a at a constant cycle. The output target TG travels toward the plasma generation region AR as passing through the target introduction port 33c. The laser device 5 irradiates the target TG supplied to the plasma generation region AR at the constant cycle with the PPL light 51a and the MPL light 52a at a constant period to generate the EUV light 20. Here, the timing at which the PPL light 51a and the MPL light 52a are output from the laser device 5 is determined based on a passage timing signal of the target TG from a timing sensor (not shown).

The EUV light 20 generated in the plasma generation region AR passes through the gas inlet port 33a, is reflected by the EUV light concentrating mirror 10, and enters the external apparatus 100 through the connection pipe 32. In the external apparatus 100, a predetermined process is performed using the EUV light 20. The intensity of the EUV light 20 generated in the plasma generation region AR is measured by the sensor 6.

More specifically, the droplet-shaped target TG supplied to the plasma generation region AR is misted by being irradiated with the PPL light 51a to form a mist-like target TGm. The mist-like target TGm is turned into plasma by being irradiated with the MPL light 52a to generate the EUV light 20. At this time, a part of the mist-like target TGm is diffused as residual mist without being turned into plasma. This residual mist includes debris, called fragments, such as fine particles of liquid tin having a certain size.

Although light including EUV light is generated by the irradiation of the target TG with the PPL light 51a, the intensity of the EUV light generated by the irradiation with the PPL light 51a is smaller than the intensity of the EUV light 20 generated by the irradiation with the MPL light 52a. The targets TG, TGm are examples of the “target” according to the technology of the present disclosure. The residual mist is an example of the “diffusion matter” according to the technology of the present disclosure.

Due to the flow of the gas from the second space S2 to the first space S1 as described above, the residual mist generated in the first space S1 is suppressed from flowing into the second space S2 where the EUV light concentrating mirror 10 is arranged.

### 1.3 Problem

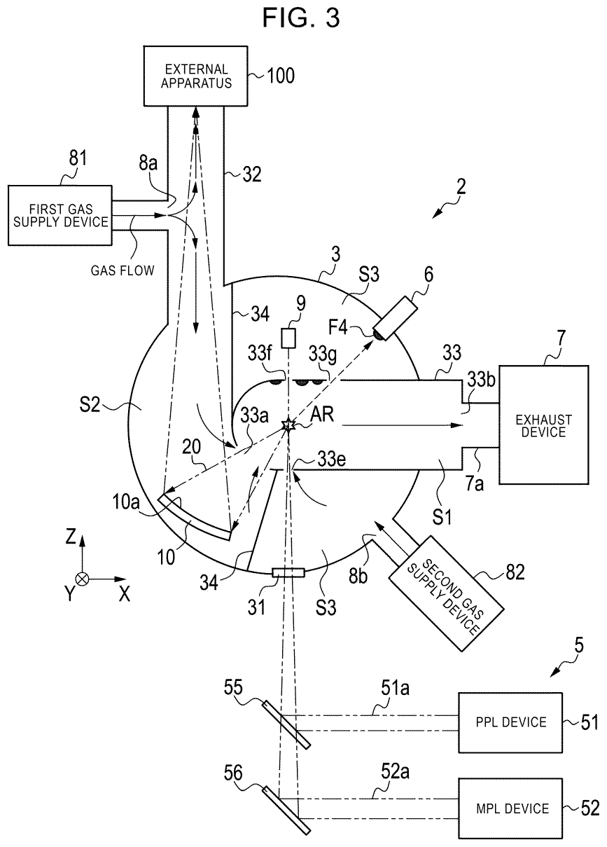

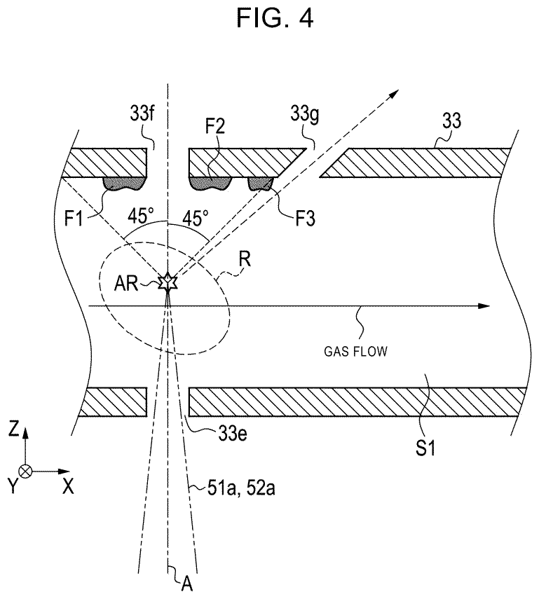

FIG. 3 shows a state of the EUV light generation apparatus 2 according to the comparative embodiment after being operated for a certain period of time. FIG. 4 is an enlarged view showing the vicinity of the plasma generation region AR in FIG. 3.

As described above, a part of the debris contained in the residual mist scattered when the mist-like target TGm is irradiated with the MPL light 52a adheres and is deposited to the inner surface of the partition wall 33 and the like without being discharged with the gas. It has been found that the deposition of debris occurs frequently in an angular region from the plasma generation region AR to an irradiation axis A of the MPL light 52a at 45 degrees.

The reference numerals F1 to F4 shown in FIGS. 3 and 4 indicate deposits of the debris. When the deposits F1, F2 occur on the inner surface of the partition wall 33 as shown in FIG. 4, the deposits F1, F2 narrow the first space S1, thereby decreasing exhaust efficiency of the gas. As a result, the gas pressure in the first space S1 increases, which may change the operation condition of the EUV light generation apparatus 2. A reference numeral R shown in FIG. 4 schematically indicates a region where the gas pressure increases.

Further, as shown in FIG. 4, a deposit F3 may occur on the inner surface of the partition wall 33 in the vicinity of the monitor opening 33g. In this case, in addition to the decrease of the exhaust efficiency of the gas, there is a possibility that the deposit F3 interferes with the optical path through which the sensor 6 monitors the plasma generation region AR, thereby blocking the observation light and causing abnormal operation of the sensor 6.

Further, as shown in FIG. 3, a deposit F4 may occur on an optical element of the sensor 6. In this case there is a possibility that the deposit F4 interferes with the optical path through which the sensor 6 monitors the plasma generation region AR, thereby blocking the observation light and causing abnormal operation of the sensor 6.

Further, a deposit (not shown) occurring in the vicinity of the target introduction port 33c may interfere with the trajectory of the target TG, which may cause abnormal generation of the EUV light 20.

Here, the partition walls 33, 34 are provided in the chamber 3 in the comparative example. Even when the partition walls 33, 34 are not provided, the same abnormality may occur due to occurrence of a deposit on the inner surface of the chamber 3 or the optical element of the sensor 6.

When the debris occurring in the chamber 3 is deposited as described above, abnormality occurs, and therefore, maintenance of the EUV light generation apparatus 2 needs to be periodically performed. When abnormality occurs frequently due to debris deposition, a maintenance interval needs to be shortened, and therefore, the operation time of the EUV light generation apparatus 2 is shortened.

An object of the present disclosure is to suppress deposition of debris in the chamber 3 and reduce occurrence of abnormality.

### 2. Embodiment

### 2.1 Configuration

The configuration of the EUV light generation apparatus 2a according to an embodiment of the present disclosure is similar to that of the EUV light generation apparatus 2 according to the comparative example except that the configuration of the laser device 5 is different.

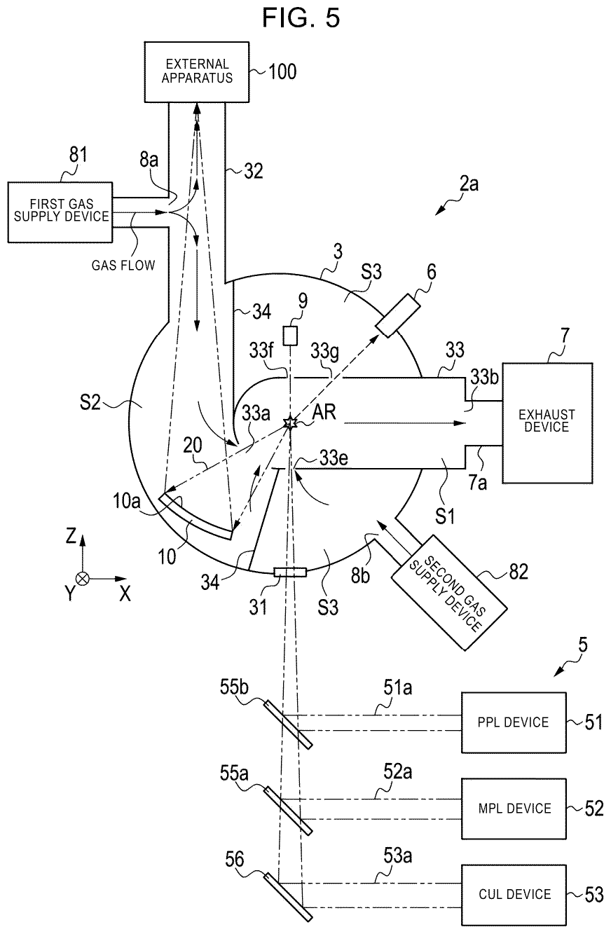

FIG. 5 schematically shows the configuration of the EUV light generation apparatus 2a according to the embodiment. FIG. 5 is a schematic view of the EUV light generation apparatus 2a as viewed in the vertical direction. In the present embodiment, the laser device 5 includes, in addition to the PPL device 51 and the MPL device 52, a clean-up laser (CUL) device 53 for outputting CUL light 53a. For example, the CUL device 53 is a Yb: YAG laser device. The CUL device 53 may be an Nd: YAG laser device, an Nd: YLF laser device, a YVO₄ laser device, or the like. The CUL light 53a is pulse laser light for decomposing the residual mist.

In the present embodiment, a wavelength λ3 of the CUL light 53a is different from the wavelength λ2 of the MPL light 52a. In the present embodiment, the wavelength λ2 of the MPL light 52a is equal to the wavelength λ1 of the PPL light 51a. In the present embodiment, the PPL light 51a, the MPL light 52a, and the CUL light 53a are linearly polarized.

In the present embodiment, a first beam combiner 55a and a second beam combiner 55b are provided to cause the optical paths of the PPL light 51a, the MPL light 52a, and the CUL light 53a to enter the chamber 3 through the window 31 with optical paths thereof integrated. The first beam combiner 55a is a dichroic mirror that transmits light having the wavelength λ3 and reflects light having the wavelength λ2. The first beam combiner 55a is arranged such that the MPL light 52a output from the MPL device 52 is incident on one surface thereof, and the CUL light 53a output from the CUL device 53 and reflected by the reflection mirror 56 is incident on the other surface thereof. The MPL light 52a is reflected by the first beam combiner 55a and the CUL light 53a is transmitted through the first beam combiner 55a, so that the optical paths of the MPL light 52a and the CUL light 53a are integrated.

The second beam combiner 55b is a polarization beam splitter that reflects s-polarized light and transmits p-polarized light. The second beam combiner 55b is arranged such that the PPL light 51a output from the PPL device 51 is incident on one surface thereof as s-polarized light, and the MPL light 52a reflected by the first beam combiner 55a and the CUL light 53a transmitted through the first beam combiner 55a are incident on the other surface thereof as p-polarized light. The PPL light 51a is reflected by the second beam combiner 55b and the MPL light 52a and the CUL light 53a are transmitted through the second beam combiner 55b, so that the optical paths of the PPL light 51a, the MPL light 52a, and the CUL light 53a are integrated.

Here, the reflection mirror 56 is not necessarily required, and the CUL light 53a output from the CUL device 53 may be directly incident on the first beam combiner 55a.

The pulse energy of the PPL light 51a is smaller than the pulse energy of the MPL light 52a. The laser device 5 outputs the PPL light 51a, the MPL light 52a, and the CUL light 53a in this order. Here, output timings of the PPL light 51a, the MPL light 52a, and the CUL light 53a are controlled by a processor (not shown).

Here, the MPL device 52 is an example of the “first pulse laser device” according to the technology of the present disclosure. The CUL device 53 is an example of the “second pulse laser device” according to the technology of the present disclosure. The PPL device 51 is an example of the “third pulse laser device” according to the technology of the present disclosure. The MPL light 52a is an example of the “first pulse laser light” according to the technology of the present disclosure. The CUL light 53a is an example of the “second laser light” according to the technology of the present disclosure. The PPL light 51a is an example of the “third pulse laser light” according to the technology of the present disclosure.

### 2.2 Operation

The operation of the EUV light generation apparatus 2a according to the present embodiment is similar to that according to the comparative example except that the operation of the laser device 5 is different.

In the present embodiment, the laser device 5 radiates the CUL light 53a every time the PPL light 51a and the MPL light 52a are radiated. Specifically, the laser device 5 irradiates, at a constant cycle, the target TG supplied to the plasma generation region AR at a certain cycle with the PPL light 51a and the MPL light 52a to generate the EUV light 20 and irradiates, with the CUL light 53a, the residual mist generated by the irradiation with the MPL light 52a.

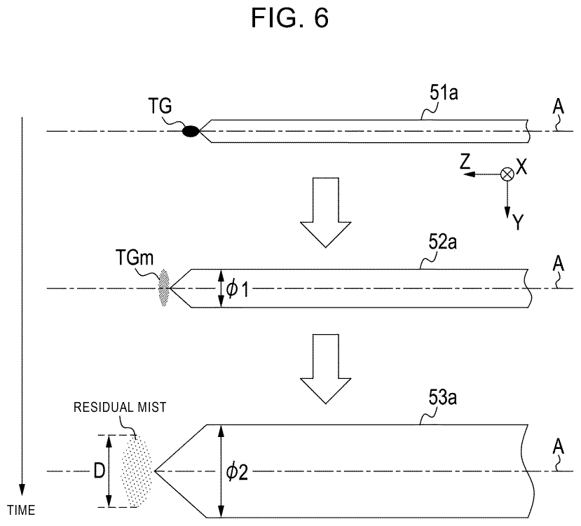

FIG. 6 schematically shows the PPL light 51a, the MPL light 52a, and the CUL light 53a radiated to one target TG. The target TG is misted by being irradiated with the PPL light 51a. The mist-like target TGm is turned into plasma by being irradiated with the MPL light 52a to generate the EUV light 20, and a part of the mist-like target TGm becomes residual mist. The residual mist is decomposed to an atomic state by being irradiated with the CUL light 53a, and is discharged to the outside of the chamber 3 by the exhaust device 7 together with the gas. Light including EUV light is also generated by the irradiation of the residual mist with the CUL light 53a. Here, the intensity of the EUV light is smaller than the intensity of the EUV light 20 generated by the irradiation of the mist-like target TGm with the MPL light 52a.

Since irradiation intervals of the PPL light 51a, the MPL light 52a, and the CUL light 53a are short, the position of the gravity center of the mist-like target TGm and the position of the gravity center of the residual mist hardly move in the Y direction, which is the vertical direction. However, the position of the gravity center of the mist-like target TGm moves along the irradiation axis A by irradiating the target TG with the PPL light 51a. The position of the gravity center of the residual mist moves along the irradiation axis A by irradiating the mist-like target TGm with the MPL light 52a. Therefore, as described above, the irradiation accuracy is improved by the irradiation of the PPL light 51a, the MPL light 52a, and the CUL light 53a along the irradiation axis A with the optical paths thereof integrated.

### 2.3 Irradiation Conditions of CUL Light

Next, various irradiation conditions of the CUL light 53a for efficiently decomposing the residual mist will be described.

### 2.3.1 Irradiation Spot Diameter

Since a diameter D of the residual mist becomes larger than the diameter of the mist-like target TGm by diffusion, an irradiation spot diameter Φ2 of the CUL light 53a in the plasma generation region AR needs to be larger than an irradiation spot diameter Φ1 of the PPL light 51a. For example, the irradiation spot diameter Φ2 is preferably in the range of 1.5 times or more and 5 times or less of the irradiation spot diameter Φ1, and more preferably in the range of 2 times or more and 3 times or less thereof. Here, the irradiation spot diameter is defined, for example, as a diameter of a portion where the intensity is 1/e² times or more of the maximum intensity in a Gaussian beam in which the intensity distribution is centrosymmetric.

### 2.3.2 Irradiation Timing

It is preferable that the CUL light 53a is irradiated to the residual mist after the intensity of the EUV light 20 generated by the irradiation of the mist-like target TGm with the MPL light 52a is decreased. This is because, when the CUL light 53a is radiated during emission of the EUV light 20, the mist contained in the mist-like target TGm is diffused and the strength of the EUV light 20 is lowered.

Specifically, it is preferable that, after the irradiation with the MPL light 52a, the CUL light 53a is radiated prior to the residual mist being diffused and becoming larger than the irradiation spot diameter Φ2 of the CUL light 53a. That is, the irradiation spot diameter Φ2 of the CUL light 53a is preferably larger than the diameter D of the residual mist at the time of irradiation with the CUL light 53a.

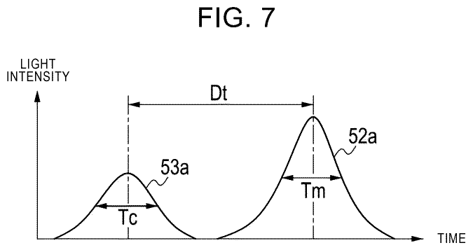

More specifically, when the pulse width of the MPL light 52a is represented by Tm, the pulse width of the CUL light 53a is represented by Tc, and the delay time of the CUL light 53a with respect to the MPL light 52a is represented by Dt, as shown in FIG. 7, it is preferable to satisfy the following expression (1).

(Tm+Tc)/2≤Dt≤100ns (1)

For example, the pulse widths Tm, Tc are each defined as full width at half maximum. The delay time Dt is defined as a difference between the time at which the intensity of the MPL light 52a is maximized and the time at which the intensity of the CUL light 53a is maximized.

### 2.3.3 Irradiation Intensity

In order to decompose the residual mist to an atomic state, the intensity of the CUL light 53a needs to be at least higher than the ablation threshold of tin. The ablation threshold of tin has been experimentally found to be, for example, 2.5×10⁷ W/cm² when the pulse energy is 0.16 mJ, the spot diameter is 100 μm, and the pulse width is 80 ns. Therefore, it is preferable that the lower limit value of the intensity of the CUL light 53a set to 2.5×10⁷ W/cm².

There is no limitation for the upper limit of the intensity of the CUL light 53a from the viewpoint of decomposing the residual mist to an atomic state. However, since the residual mist is liquid-state tin, high energy ions are generated by radiating high intensity laser light, and the generated ions may collide with the optical elements such as the EUV light concentrating mirror 10 in the chamber 3 and cause damage thereto. A gas is supplied into the chamber 3 to protect the optical elements from such high energy ions, and the properties of the gas are set based on the energy of ions generated by the irradiation with the MPL light 52a. Therefore, when the energy of ions generated by the irradiation with the CUL light 53a is higher than that by the irradiation with the MPL light 52a owing to that the intensity of the CUL light 53a is increased, the optical elements cannot be protected by the gas and the optical elements are damaged. Since the energy of the generated ions is substantially proportional to the intensity, for example, if the upper limit of the intensity of the CUL light 53a is 1/10 times the intensity of the MPL light 52a, the damage to the optical elements becomes negligible. From the above, for example, the upper limit of the intensity of the CUL light 53a is preferably 5×10⁹ W/cm².

### 2.3.4 Pulse Width

The pulse width of the CUL light 53a is simply required to be within a range in which the liquid-state tin can be ablated, and it has been experimentally found that the lower limit value thereof may be 20 ns. Further, the pulse width of the CUL light 53a is preferably long to cause the reaction time with tin to be long. It has been experimentally found that the upper limit of the pulse width of the CUL light 53a is preferably 200 ns. That is, the pulse width of the CUL light 53a is preferably not less than 20 ns and not more than 200 ns. For example, the pulse width of the CUL light 53a is preferably about 100 ns.

### 2.4 Effect

In the present embodiment, by irradiating, with the CUL light 53a, the residual mist generated by the irradiation with the MPL light 52a, the residual mist is decomposed to an atomic state and discharged to the outside of the chamber 3 together with the gas, so that the deposition of debris on the inner surface of the partition wall 33 and the like is suppressed. Thus, occurrence of abnormality in the EUV light generation apparatus 2 is reduced. Specifically, a decrease in the exhaust efficiency of the gas, abnormal operation of the sensor 6, abnormal generation of the EUV light 20, and the like are reduced, and the maintenance interval is extended. Thus, the operation time of the EUV light generation apparatus 2 is improved.

### 3. Modification

Various modifications of the embodiment will be described below.

In the above embodiment, the wavelength λ1 of the PPL light 51a and the wavelength λ2 of the MPL light 52a are the same, but may be different from each other. That is, the wavelengths λ1, λ2, and λ3 may be set to different wavelengths. In this case, both the first beam combiner 55a and the second beam combiner 55b may be dichroic mirrors. For example, the first beam combiner 55a may be a dichroic mirror that transmits light having the wavelength λ3 and reflects light having the wavelength λ2, as in the above-described embodiment. Further, the second beam combiner 55b may be a dichroic mirror that transmits light having the wavelength λ3 and light having the wavelength λ2 and reflects light having the wavelength λ1.

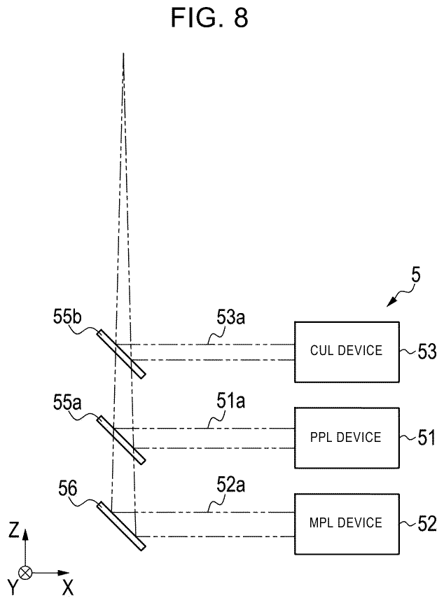

Further, in the above embodiment, the PPL device 51, the MPL device 52, and the CUL device 53 are arranged in this order from the downstream side of the optical path, but as shown in FIG. 8, may be arranged in the order of the CUL device 53, the PPL device 51, and the MPL device 52 from the downstream side. In this case, the first beam combiner 55a is a polarization beam splitter that reflects s-polarized light and transmits p-polarized light. The first beam combiner 55a is arranged such that the PPL light 51a output from the PPL device 51 is incident on one surface thereof as s-polarized light, and the MPL light 52a output from the MPL device 52 and reflected by the reflection mirror 56 is incident on the other surface thereof as p-polarized light.

In this case, the second beam combiner 55b is a dichroic mirror that transmits light having the wavelength λ1 and light having the wavelength λ2 and reflects light having the wavelength λ3. The second beam combiner 55b is arranged such that the CUL light 53a output from the CUL device 53 is incident on one surface thereof, and the MPL light 52a transmitted through the first beam combiner 55a and the PPL light 51a reflected by the first beam combiner 55a are incident on the other surface thereof. The CUL light 53a is reflected by the second beam combiner 55b and the PPL light 51a and the MPL light 52a are transmitted through the second beam combiner 55b, so that the optical paths of the PPL light 51a, the MPL light 52a, and the CUL light 53a are integrated.

In the example shown in FIG. 8 as well, the reflection mirror 56 is not necessarily required, and the MPL light 52a output from the MPL device 52 may be directly incident on the first beam combiner 55a. Further, in the example shown in FIG. 8 as well, when the wavelengths λ1, λ2, and λ3 differ from each other, both the first beam combiner 55a and the second beam combiner 55b may be dichroic mirrors.

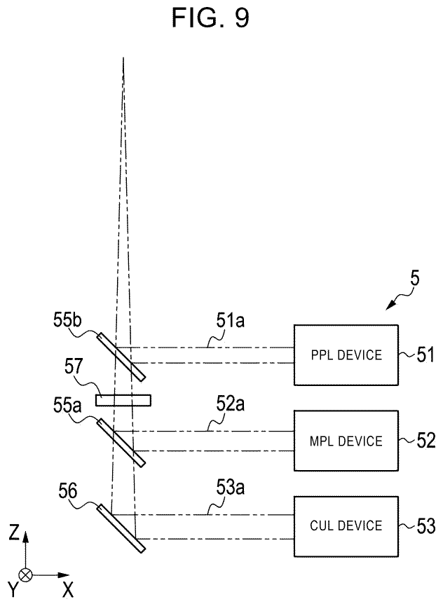

Further, it is also possible that the wavelengths λ1, λ2, and λ3 are set to be all the same. In this case, for example, as shown in FIG. 9, an electro-optical modulator 57 capable of temporally changing the polarization direction of the light is arranged on the optical path between the first beam combiner 55a and the second beam combiner 55b. The electro-optical modulator 57 is controlled by a processor (not shown).

In the example shown in FIG. 9, the first beam combiner 55a and the second beam combiner 55b are both polarization beam splitters that reflect s-polarized light and transmit p-polarized light. The first beam combiner 55a is arranged such that the MPL light 52a output from the MPL device 52 is incident on one surface thereof as s-polarized light, and the CUL light 53a output from the CUL device 53 and reflected by the reflection mirror 56 is incident on the other surface thereof as p-polarized light.

The MPL light 52a reflected by the first beam combiner 55a and the CUL light 53a transmitted through the first beam combiner 55a enter the electro-optical modulator 57. The electro-optical modulator 57 outputs the CUL light 53a without changing the polarization direction, and outputs the MPL light 52a with changing the polarization direction by 90 degrees.

The second beam combiner 55b is arranged such that the PPL light 51a output from the PPL device 51 is incident on one surface thereof as s-polarized light, and the MPL light 52a and the CUL light 53a output from the electro-optical modulator 57 are incident on the other surface thereof as p-polarized light. The PPL light 51a is reflected by the second beam combiner 55b and the MPL light 52a and the CUL light 53a are transmitted through the second beam combiner 55b, so that the optical paths of the PPL light 51a, the MPL light 52a, and the CUL light 53a are integrated.

The configuration for integrating the optical paths of the PPL light 51a, the MPL light 52a, and the CUL light 53a can be variously modified in addition to the above modification. The optical path of the PPL light 51a and the optical path of the MPL light 52a are only required to be partially overlapped with each other. Further, the optical path of the MPL light 52a and the optical path of the CUL light 53a are only required to be partially overlapped with each other.

In addition, the polarization directions of the two beams of light incident on the polarization beam splitter described in the above embodiment and the modifications thereof may be reversed. Specifically, the polarization beam splitter may be arranged such that the s-polarized light described above is p-polarized light and the p-polarized light described above is s-polarized light. Further, the polarization directions of the light reflected and the light transmitted by the polarization beam splitter may be reversed. Specifically, the polarization beam splitter may reflect p-polarized light and transmit s-polarized light.

In the above embodiment and the modifications thereof, the PPL device 51 is provided in the laser device 5, but the PPL device 51 may not be provided. That is, the droplet-shaped target TG may be irradiated with the MPL light 52a.

Here, the PPL device 51 is not essential. However, owing to that the droplet-shaped target TG is turned into the mist-like target TGm by the PPL device 51, the generation efficiency of the EUV light 20 is improved and the decomposition efficiency of the residual mist by the CUL light 53a is improved. This is because, by generating the mist-like target TGm, fragments contained in the residual mist generated by the irradiation with the MPL light 52a are decomposed to a smaller extent.

In the above embodiment, the partition walls 33, 34 are provided in the chamber 3, but the partition walls 33, 34 may not be provided in the chamber 3. Alternatively, only the partition wall 33 among the partition walls 33, 34 may be provided in the chamber 3.

### 4. Electronic Device Manufacturing Method

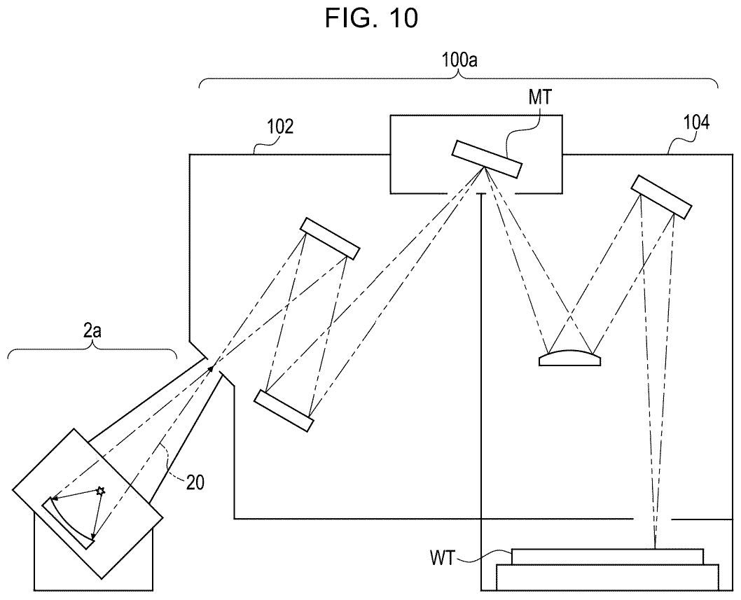

FIG. 10 schematically shows the configuration of the exposure apparatus 100a connected to the EUV light generation apparatus 2a. In FIG. 10, the exposure apparatus 100a as the external apparatus 100 includes a mask irradiation unit 102 and a workpiece irradiation unit 104. The mask irradiation unit 102 irradiates a mask pattern on a mask table MT via a reflection optical system with the EUV light 20 incident from the EUV light generation apparatus 2a. The workpiece irradiation unit 104 images the EUV light 20 reflected by the mask table MT onto a workpiece (not shown) placed on the workpiece table WT via a reflection optical system. The workpiece is a photosensitive substrate such as a semiconductor wafer on which photoresist is applied. The exposure apparatus 100a synchronously translates the mask table MT and the workpiece table WT to expose the workpiece to the EUV light 20 reflecting the mask pattern. Through the exposure process as described above, a device pattern is transferred onto the semiconductor wafer, thereby an electronic device can be manufactured.

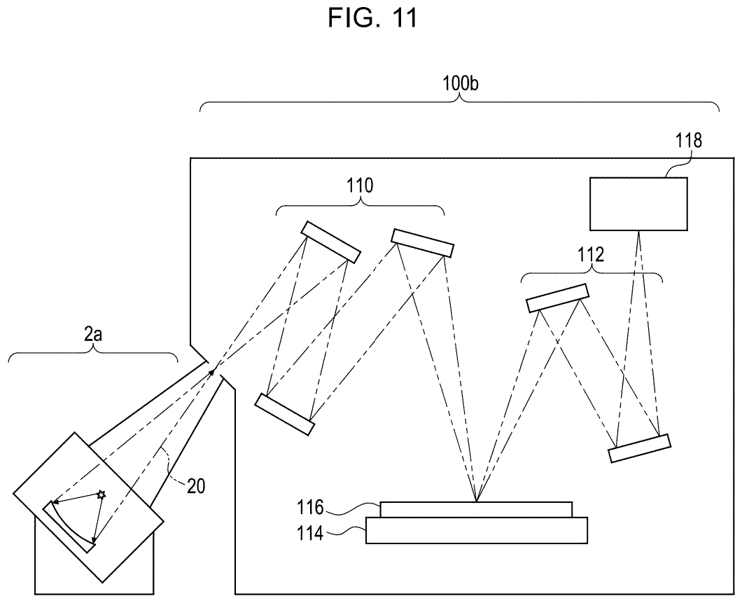

FIG. 11 schematically shows the configuration of the inspection apparatus 100b connected to the EUV light generation apparatus 2a. In FIG. 11, the inspection apparatus 100b as the external apparatus 100 includes an illumination optical system 110 and a detection optical system 112. The EUV light generation apparatus 2a outputs, as a light source for inspection, the EUV light 20 to the inspection apparatus 100b. The illumination optical system 110 reflects the EUV light 20 incident from the EUV light generation apparatus 2a to illuminate a mask 116 placed on a mask stage 114. Here, the mask 116 conceptually includes a mask blanks before a pattern is formed. The detection optical system 112 reflects the EUV light 20 from the illuminated mask 116 and forms an image on a light receiving surface of a detector 118. The detector 118 having received the EUV light 20 acquires an image of the mask 116. The detector 118 is, for example, a time delay integration (TDI) camera. Inspection for a defect of the mask 116 is performed based on the image of the mask 116 obtained by the above-described steps, and a mask suitable for manufacturing an electronic device is selected using the inspection result. Then, the electronic device can be manufactured by exposing and transferring the pattern formed on the selected mask onto the photosensitive substrate using the exposure apparatus 100a.

The description above is intended to be illustrative and the present disclosure is not limited thereto. Therefore, it would be obvious to those skilled in the art that various modifications to the embodiment of the present disclosure would be possible without departing from the spirit and the scope of the appended claims. The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of the any thereof and any other than A, B, and C.

What is claimed is:

1. An EUV light generation apparatus, comprising:
a chamber;
a target supply device configured to supply a target into the chamber;
a first pulse laser device configured to irradiate the target with first pulse laser light in a plasma generation region in the chamber;
an EUV light concentrating mirror arranged in the chamber and configured to reflect EUV light, radiated from the plasma generation region, toward an external apparatus; and
a second pulse laser device configured to irradiate a diffusion matter, diffused by the irradiation with the first pulse laser light, with second pulse laser light having an irradiation spot diameter larger than an irradiation spot diameter of the first pulse laser light,
an intensity of the EUV light generated by the irradiation with the second pulse laser light being smaller than an intensity of the EUV light generated by the irradiation with the first pulse laser light.

2. The EUV light generation apparatus according to claim 1,
wherein the irradiation spot diameter of the second pulse laser light is larger than a diameter of the diffusion matter.

3. The EUV light generation apparatus according to claim 1,
wherein the irradiation spot diameter of the second pulse laser light is in a range of 1.5 times or more and 5 times or less of the irradiation spot diameter of the first pulse laser light.

4. The EUV light generation apparatus according to claim 1,
wherein the irradiation spot diameter of the second pulse laser light is in a range of 2 times or more and 3 times or less of the irradiation spot diameter of the first pulse laser light.

5. The EUV light generation apparatus according to claim 1,
wherein the second pulse laser device irradiates the diffusion matter with the second pulse laser light after the intensity of the EUV light generated by the irradiation with the first pulse laser light is decreased.

6. The EUV light generation apparatus according to claim 5,
wherein, when a pulse width of the first pulse laser light is Tm, a pulse width of the second pulse laser light is Tc, and a delay time of the second pulse laser light with respect to the first pulse laser light is Dt, (Tm+Tc)/2≤Dt≤100 ns is satisfied.

7. The EUV light generation apparatus according to claim 1,
wherein an intensity of the second pulse laser light is smaller than an intensity of the first pulse laser light.

8. The EUV light generation apparatus according to claim 7,
wherein the intensity of the second pulse laser light is 1/10 times or less of the intensity of the first pulse laser light.

9. The EUV light generation apparatus according to claim 1,
wherein a pulse width of the second pulse laser light is in a range of 20 ns or more and 200 ns or less.

10. The EUV light generation apparatus according to claim 1,
wherein the second pulse laser device irradiates the diffusion matter with the second pulse laser light each time the target is irradiated with the first pulse laser light.

11. The EUV light generation apparatus according to claim 1,
wherein an optical path of the second pulse laser light is at least partially overlapped with an optical path of the first pulse laser light.

12. The EUV light generation apparatus according to claim 1,
further comprising a third pulse laser device configured to irradiate the target with third pulse laser light prior to the first pulse laser light.

13. The EUV light generation apparatus according to claim 12,
wherein an intensity of the EUV light generated by the irradiation with the third pulse laser light is smaller than the intensity of the EUV light generated by the irradiation with the first pulse laser light.

14. The EUV light generation apparatus according to claim 12,
wherein an optical path of the second pulse laser light is at least partially overlapped with an optical path of the first pulse laser light and an optical path of the third pulse laser light.

15. The EUV light generation apparatus according to claim 14,
further comprising a first beam combiner and a second beam combiner that integrate the optical path of the first pulse laser light, the optical path of the second pulse laser light, and the optical path of the third pulse laser light.

16. The EUV light generation apparatus according to claim 1, further comprising:
a gas supply device configured to supply a gas into the chamber; and
an exhaust device configured to exhaust the gas from the chamber.

17. The EUV light generation apparatus according to claim 16,
further comprising a partition wall that surrounds the plasma generation region and is connected to the exhaust device.

18. The EUV light generation apparatus according to claim 17,
further comprising a sensor configured to measure the intensity of the EUV light generated in the plasma generation region via a monitor opening formed in the partition wall.

19. An electronic device manufacturing method, comprising:
outputting EUV light generated by an EUV light generation apparatus to an exposure apparatus; and
exposing a photosensitive substrate to the EUV light in the exposure apparatus to manufacture an electronic device,
the EUV light generation apparatus including:
a chamber;
a target supply device configured to supply a target into the chamber;
a first pulse laser device configured to irradiate the target with first pulse laser light in a plasma generation region in the chamber;
an EUV light concentrating mirror arranged in the chamber and configured to reflect the EUV light, radiated from the plasma generation region, toward an external apparatus; and
a second pulse laser device configured to irradiate a diffusion matter, diffused by the irradiation with the first pulse laser light, with second pulse laser light having an irradiation spot diameter larger than an irradiation spot diameter of the first pulse laser light, and
an intensity of the EUV light generated by the irradiation with the second pulse laser light being smaller than an intensity of the EUV light generated by the irradiation with the first pulse laser light.

20. An electronic device manufacturing method, comprising:
inspecting a defect of a mask by irradiating the mask with EUV light generated by an EUV light generation apparatus;
selecting a mask using a result of the inspection; and
exposing and transferring a pattern formed on the selected mask onto a photosensitive substrate,
the EUV light generation apparatus including:
a chamber;
a target supply device configured to supply a target into the chamber;
a first pulse laser device configured to irradiate the target with first pulse laser light in a plasma generation region in the chamber;
an EUV light concentrating mirror arranged in the chamber and configured to reflect the EUV light, radiated from the plasma generation region, toward an external apparatus; and
a second pulse laser device configured to irradiate a diffusion matter, diffused by the irradiation with the first pulse laser light, with second pulse laser light having an irradiation spot diameter larger than an irradiation spot diameter of the first pulse laser light, and
an intensity of the EUV light generated by the irradiation with the second pulse laser light being smaller than an intensity of the EUV light generated by the irradiation with the first pulse laser light.
